(19) United States
(12) Patent Application Publication
(10) Pub. No.: US 2005/0180109 A1
(43) Pub. Date: Aug. 18, 2005

(54) Self-excited vibration heat pipe and computer with the heat pipe

(76) Inventors: Yoshiro Miyazaki, Fukui (JP); Kaneko Miyazaki, Fukui (JP)

Correspondence Address: FLYNN THIEL BOUTELL & TANIS, P.C., 2026 RAMBLING ROAD, KALAMAZOO, MI, 49008-1699, US

(21) Appl. No.: 10/511,778

(22) PCT Filed: Apr. 14, 2003
(86) PCT No.: PCT/JP03/04678

(30) Foreign Application Priority Data
Apr. 16, 2002 (JP) 2002112779
Apr. 16, 2002 (JP) 2002112780
Jan. 17, 2003 (JP) 2003009026
Jan. 17, 2003 (JP) 2003009027

(51) Int. Cl. H05K 7/20

(52) U.S. Cl. 361/700

(57) ABSTRACT

The present invention is to provide a heat pipe which is high in heat transfer performance and reliability and can be low priced, compact and lightweight, and has flexibility, and a computer provided with the heat pipe. At least a part of a conduit (1) constituting a container of a self-excited oscillation heat pipe is formed in a shape having flexibility such as a waved bent shape. Alternatively, at least a part of the container of the self-excited oscillation heat pipe is formed of a material having flexibility such as super elastic alloys.

### TECHNICAL FIELD

The present invention relates to a self-excited oscillation heat pipe having flexibility and a computer provided with the self-excited oscillation heat pipe.

### BACKGROUND TECHNOLOGY

As a heat pipe which has been put into practice so far, there are typically three examples, namely, a wick type heat type, an closed two-phase thermo-siphon and a self-excited oscillation heat pipe. As a structure of a fluid channel, there are a single pipe type in which both ends of the fluid channel are closed and a loop type in which both ends of the fluid channel are connected to each other.

In the case of installing such a heat pipe to a movable portion of a unit, the heat pipe is needed to be flexible. With the wick type heat pipe and the closed two-phase thermo-siphon, it is proposed to provide bellows at a part of fluid channel constituting a container in order to obtain a heat pipe having flexibility With the single pipe type of the wick type heat pipe and the closed two-phase thermo-siphon, vapor and liquid are separated such that liquid normally exists in an inner wall of the tube and vapor exists in the central portion of the tube wherein liquid and vapor flow oppositely when the heat pipe operates. The wick type heat pipe is provided with a capillary structure in an inner wall thereof to maintain distribution and flow of working fluid. Further, even in the case of the closed two-phase thermo-siphon, a capillary structure is frequently provided in an inner wall thereof so as to stably maintain distribution and flow of working fluid. The capillary structure has to continuously exist over a heating portion and a cooling portion of a heat pipe. However, it is technically very difficult to provide the capillary structure on an inner surface of the bellows.

Accordingly, there is proposed a method to provide a capillary structure at the central portion of the pipe and this capillary structure is connected to a capillary structure provided in an inner wall of a heating portion and that of a cooling portion (e.g. see Shimizu, A., “A Flexible Heat Pipe with Carbon Fiber Arterial Wick”, proceedings of The 11^{th} International Heat Pipe Conference, The Japan Association for Heat Pipes, September, 1999, pp 149-153).

There is a system which is a so-called capillary pumped loop (CLP) or a loop heat pipe (LHP) as a loop type of the wick type heat pipe wherein working fluid flows in one direction of the loop owing to a capillary force. Since there is no need for providing a capillary structure at least at a vapor transfer pipe directing from an evaporation portion to a condensation portion and at a liquid transfer pipe directing from the condensation portion to the evaporation portion, and hence there is an example where the bellows is provided at these portions (e.g. “Practical Heat Pipe”, published by Nikkan Kogyo Newspaper Co., The Japan Association for Heat Pipes, July, 2001, pp 254-259).

Regarding a loop type of the closed two-phase thermo-siphon or the self-excited oscillation heat pipe, there is no example of a proposal or practice for providing a flexibility.

Further, there is proposed a heat transfer unit for rotatably connecting two heat pipes via a slidable contact type heat exchanger without rendering the heat pipes flexible (e.g. “Practical Heat Pipe”, 2^{nd} edition published by Nikkan Kogyo Newspaper Co., The Japan Association for Heat Pipes, July, 2001, pp 129-133).

Since the wick type heat pipe of the single pipe type or an closed two-phase thermo-siphon of the single pipe type is relatively simple in structure, it is possible to provide a product which is low in price and high in reliability, and also the dimensions of the pipe can be reduced to some extent. However, if the bellows is provided on the conduit, the capillary structure which has been conventionally provided on the inner wall of the pipe is needed to be provided remote from the inner wall of the pipe, rendering the capillary structure complex. Accordingly, there arises a problem that the heat pipe is difficult to be rendered compact and lightweight associated with rendering in a small pipe, leading to the increase in price and trouble.

According to the wick type heat pipe of the loop type or an closed two-phase thermo-siphon of the loop type, there are a vapor transfer pipe through which only vapor flows and a liquid transfer pipe through which only liquid flows, and these portions do not require a capillary structure. Accordingly, if there is provided a bellows at the vapor transfer pipe and the liquid transfer pipe, it is not necessary to change the internal capillary structure, and it does not make an impact on the operation of working fluid, which does not arise a problem of the increase in price and the increase in troubles. However, since the evaporation pipe of the capillary pumped loop or that of the loop heat pipe has a complex capillary structure and fluid channel to require high precision in manufacturing and assembling thereof, resulting in very expensive, and hence it is limited to a special purpose such as a heat control in a spacecraft. Further, there is a technical problem of the possibility of occurrence of trouble in starting or re-priming. Further, there is a problem that the evaporation pipe is difficult to be rendered in a small pipe and it is heavy in weight and large in volume. There is a restriction in the closed two-phase thermo-siphon of the loop type that a cooling portion has to be installed at a position higher than a heating portion, and a head to be obtained associated with rendering compact becomes small, causing a problem of the reduction of heat transfer performance.

A method of connecting two single heat pipes by a sliding contact type heat exchanger having a hinge function or a flexible good heat conductor has a problem that thermal resistance in each heat pipe is added and thermal resistance is added at the connection portion, thereby lowering a heat transfer performance compared with the single heat pipe. Further, there is a problem of leading to the increase in troubles and price as the number of parts increases.

In the prior art set forth above, there is a disclosure of an example for employing a heat transfer unit comprised of a sliding contact type heat exchanger in a computer provided with a foldable display unit as an example for applying the heat pipe to a unit having a movable portion (see the foregoing “Practical Heat Pipe”, pp 129-133). In such a computer, although there are many cases where heat radiation from a CPU and so forth is effected by a heat sink or a radiation plate for natural cooling, or a heat sink or a radiation plate provided with a cooling fan provided on a body unit, the heat pipe is employed for the purpose of improving heat radiation efficiency of the heat sink or the radiation plate or for transferring heat to the heat sink which is remote from the CPU.

There is a limit in capacity for providing a heat sink or a cooling fan to a main unit of a computer provided with a display unit foldably attached to the computer, and it is difficult to obtain an effective radiation surface because a key board is provided on the surface of the main unit of the computer. Accordingly, such a computer can only mount a CPU which is small in power consumption and inferior in performance compared with a so-called desk top computer which has a display unit remote from a main unit has a relatively large capacity. There also arises a problem that noise increases when the flow rate of the cooling air increases so as to increase the cooling capacity of the cooling fan.

Although there is conceived that heat generated in the CPU and so forth mounted on the main unit is transferred to the radiation surface provided on the backside of the display unit to radiate therein, because a sufficient heat radiation capacity is not obtained by the main unit alone, if the single heat pipe is disposed over the main unit and the radiation surface provided on the backside of the display unit, the heat pipe is deformed when the display unit is folded or extended. Accordingly, to solve this problem, there is proposed the foregoing radiation unit in which heat pipes are disposed on the main unit and the radiation surface provided on the backside of the display unit, wherein these heat pipes are connected to each other via the sliding contact type heat exchanger having a hinged function.

However, the radiation unit for connecting two heat pipes via the sliding contact type heat exchanger having a hinge function has a problem of the decrease in heat radiation performance because thermal resistance in each heat pipe is added, and also contact thermal resistance relative to the slide contact type heat exchanger is added compared with the radiation unit in which the single heat pipe is disposed. Further, there is a problem of the increase in weight or volume, troubles and price caused by the increase of the number of parts which makes the structure complex.

In addition to the heat pipes, there is employed a radiation unit in which a fluid loop for circulating cooling water by use of a pump is disposed over the main unit and the radiation surface provided on the backside of the display unit so as to transfer heat generated in a CPU and so forth to the radiation surface (e.g. see Tsuyoshi Nakagawa, “A water-cooling module for a notebook personal computer”, Hitachi Review, November, 2002).

However, the fluid loop employing the pump requires a pump, a water tank and so forth, thereby increasing the number of parts, and rendering the structure complex, and providing mechanical movable parts, which causes a problem of the increase in weight and volume thereof, the increase in troubles and price. Further, there causes problems that a power for driving the pump is needed, the heat caused by the power consumption is increased and the working hour of a battery is reduced.

### DISCLOSURE OF THE INVENTION

It is an object of the present invention to provide a flexible heat pipe which is high in heat transfer performance and reliability, capable of being low priced, and compact and lightweight, and a computer provided with the heat pipe.

The self-excited oscillation heat pipe of the present invention charging working fluid in a fluid channel reciprocating multiple times between a heating portion and a cooling portion, wherein at least a part of a container constituting the fluid channel has flexibility and can be disposed at a portion which is deployable, foldable and deformable. Further, at least a part of a conduit constituting the container of the self-excited oscillation heat pipe has a flexible shape. Still further, at least a part of the conduit constituting the container of the self-excited oscillation heat pipe has a coiled shape. Yet further, at least a part of the conduit constituting the container of the self-excited oscillation heat pipe has a waved bent shape. More still further, at least a part of the conduit constituting the container of the self-excited oscillation heat pipe is formed of a bellows.

Further, at least a part of the container of the self-excited oscillation heat pipe is constituted by a material having flexibility. Still further, at least a part of the container of the self-excited oscillation heat pipe is constituted by super elastic alloys or supper elastic plastic alloys.

Further, at least a part of a conduit disposed on a heat transfer surface of the conduit constituting the container of the self-excited oscillation heat pipe has flexibility Still further, the heat transfer surface is formed inside clothing and the conduit is disposed inside the clothing.

Further, at least a part of the container of the self-excited oscillation heat pipe other than the container disposed on the heat transfer surface has flexibility Still further, the self-excited oscillation heat pipe is disposed over a main unit of a spacecraft which mounts electronic equipment thereon and a radiation surface which is connected to the main unit to be foldable in the main unit and deployable from the main unit.

The self-excited oscillation heat pipe defined herein is a heat pipe for driving working fluid by self-excitedly generated pressure oscillation. As a typical structure of the self-excited oscillation heat pipe, there is a heat pipe wherein working fluid having a quantity which is around a half of the volume of fluid channel is charged in a small fluid channel which reciprocates multiple times between a heating potion and a cooling portion. There exist at least three configurations as the fluid channel of the self-excited oscillation heat pipe having the forgoing structure, namely, one fluid channel which is closed at least at both ends, one fluid channel having both ends connected to each other to constitute a loop, and a fluid channel provided with a check valve at the loop.

The flexibility which the self-excited oscillation heat pipe of the present invention has means properties not to deteriorate a function of the container caused by repeated deformation of the container. In the case of the deformation of the container, there is exemplified a case where the container of the self-excited oscillation heat pipe is deformed in response to the change of shape of the heat transfer surface on which the self-excited oscillation heat pipe is disposed or in response to the change of relative positions or angulars of the multiple heat transfer surfaces on which the self-excited oscillation heat pipe is disposed.

It is preferable, as the properties of flexibility, that the deterioration of the function does not occur even if the container is repeatedly bent at the curvature radius which is several times or several ten times as large as the diameter of the fluid channel of the self-excited oscillation heat pipe.

Since the self-excited oscillation heat pipe of the present invention is configured as set forth above, the following features are attained.

Since the deformation of the conduit, the attachment of the bellows and so forth hardly influence upon the operation of working fluid according to the self-excited oscillation heat pipe of the present invention, it is possible to provide a self-excited oscillation heat pipe having flexibility without accompanied by the deterioration of heat transfer properties.

Since the self-excited oscillation heat pipe does not need a capillary structure on a wall surface of the fluid channel such as wick and so forth, the deformation of the container, the attachment of bellows and so forth are easy, and hence it is possible to provide a self-excited oscillation heat pipe which is low priced, and has high reliable flexibility.

Further since the self-excited oscillation heat pipe can be configured by a small pipe compared with heat pipes of other types, the self-excited oscillation heat pipe having flexibility can cope with bending at small curvature radius.

Yet further, since the entire heat pipe including a portion to be disposed on the heat transfer surface of the self-excited oscillation heat pipe can be configured by a small pipe, it is possible to provide a self-excited oscillation heat pipe having flexibility as the entire heat pipe.

The self-excited oscillation heat pipe has flexibility having the foregoing properties, and it is possible to provide a heat pipe provided with properties of the self-excited oscillation heat pipe which is low priced, high reliability, compact and lightweight and high performance, and can be operated without depending on the gravity.

In the self-excited oscillation heat pipe having flexibility, it is possible to dispose a single heat pipe which extends over heat transfer surfaces capable of changing in distance between plural heat transfer surfaces and foldable, deployable and so forth.

Accordingly, compared with a method of disposing a plurality of heat pipes via a sliding contact type heat exchanger, and so forth, the self-excited oscillation heat pipe on which a single heat pipe can be disposed and which is high in heat transfer performance and reliability, and provide heat transfer means at low price.

Further, it is possible to dispose the flexible self-excited oscillation heat pipe on the heat transfer surface which is variable in shape.

A computer according to the present invention comprising a main unit in which at least a CPU is housed and a display unit foldably attached to the main unit, wherein a self-excited oscillation heat pipe having flexibility at least at a part of a container is disposed over the main unit and a backside of the display unit. Further, the self-excited oscillation heat pipe has a flexible shape at least at a part of a conduit constituting the container. Still further, the self-excited oscillation heat pipe has a coiled shape at least at a part of the conduit constituting the container. Yet further, the self-excited oscillation heat pipe has a waved bent shape at least at a part of the conduit constituting the container. More still further, the self-excited oscillation heat pipe is formed of a bellows at least at a part of the conduit constituting the container.

More still further, at least a part of the container of the self-excited oscillation heat pipe is constituted by a material having flexibility. Still further, at least a part of the container of the self-excited oscillation heat pipe is constituted by super elastic alloys or supper elastic plastic alloys.

More still further, a part of the container of the self-excited oscillation heat pipe is connected to a CPU or a radiation member of the CPU in an excellent heat transfer state. Further, a fan is provided on the radiation surface provided on the backside of the display unit.

Meanwhile, a so-called note book personal computer is exemplified as the computer. The flexibility of the self-excited oscillation heat pipe is preferable to have such properties that the display unit can be folded, extended, and the self-excited oscillation heat pipe is not deteriorated in function by a stress which is generated in the container when the display unit is repeatedly folded and extended. Still further, “an excellent heat transfer state” means a small thermal resistance in a contact surface between a part of the container of the self-excited oscillation heat pipe, the CPU or the radiation member of the CPU.

The computer of the present invention can provide a radiation unit owing to the foregoing configuration which can cope with the increase of the amount of heat generated in the main unit and does not require a power for the operation thereof, and is lightweight and high in heat transfer performance and reliability, and is easy and low priced in the manufacture thereof.

The self-excited oscillation heat pipe can be disposed in a state where the single heat pipe can be disposed over the radiation surface which is provided on the backside of the display unit foldably attached to the main unit and the main unit so as to allow the display unit to be foldable and deployable owing to the flexibility of the self-excited oscillation heat pipe.

Since the configuration becomes simpler compared with the other systems by use of the self-excited oscillation heat pipe, it becomes lightweight and has less trouble and can be manufactured with ease. Further, since the working fluid directly reciprocates between the main unit and the radiation surface to transfer heat, it has properties capable of high heat transfer performance compared with a radiation unit in which two heat pipes can be connected to each other via a slide contact type heat exchanger having a hinge function.

Further, since the radiation unit employing the self-excited oscillation heat pipe operates passively without using a power generated by a pump and so forth, it has features having no increase in power compared with a radiation unit employing a fluid loop in which cooling water is circulated by use of the pump. Accordingly, it is possible to provide the radiation unit employing the self-excited oscillation heat pipe which does not requires a power for operation thereof, and is lightweight and high in transfer performance and reliability, and is also easy and low priced in the manufacture relative to the computer provided with the foldable display unit.

Since the computer provided with the foldable display unit becomes high in radiation performance because of the provision of the radiation unit employing the self-excited oscillation heat pipe compared with that having no radiation surface at the backside of the display unit, since it can cope with the increase of heat generated in a CPU and so forth in the main unit, so that a CPU having high performance and large power consumption can be mounted on the computer.

Alternatively, since the computer provided with the foldable display unit becomes high in radiation performance because of the provision of the radiation unit employing the self-excited oscillation heat pipe compared with that which does not employ the backside of the display unit as the radiation surface, it can provide a computer provided with a foldable display unit which is low in noise without using a cooling fan.

### BRIEF DESCRIPTION OF DRAWINGS

FIG. 1 is a schematic view showing an embodiment of a self-excited oscillation heat pipe of the present invention.

FIG. 2 is a longitudinal sectional view relating to a conduit of the self-excited oscillation heat pipe.

FIG. 3 is a view of an example relating to shapes of conduits having flexibility.

FIG. 4 is a schematic view showing another embodiment of a self-excited oscillation heat pipe of the present invention.

FIG. 5 is a schematic perspective view relating to an embodiment of a computer of the present invention.

FIG. 6 is a schematic view showing an example of the configuration of a conduit of the self-excited oscillation heat pipe.

FIG. 7 is a schematic view showing another example of the configuration of a conduit of the self-excited oscillation heat pipe.

FIG. 8 is a schematic view showing yet another example of the configuration of a conduit of the self-excited oscillation heat pipe.

### BEST MODE FOR CARRYING OUT THE INVENTION

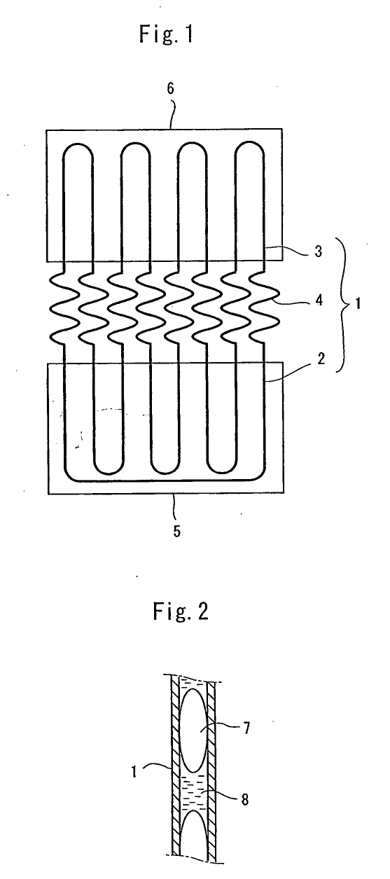

In FIG. 1, a conduit 1 of a self-excited oscillation heat pipe comprises a conduit part 2, a conduit part 3, and a conduit part 4, wherein the conduit part 2 is disposed on a heating part 5, the conduit part 3 is disposed on the cooling part cooling part 6, the conduit part 2 and the conduit part 3 are connected each other by the conduit part 4, and the conduit 1 is disposed to reciprocate multiple times between the heating part 5 and the cooling part 6.

The conduit part 4 is formed by bending the conduit in a waved bent shape to have flexibility, and hence the heating part 5 and the cooling part 6 can be foldable.

A working fluid vapor 7 and a working fluid liquid 8 are distributed inside the conduit 1 of the self-excited oscillation heat pipe as shown in FIG. 2, whereby heat transfer from the heating part 5 to the cooling part 6 is effected by reciprocation of the working fluid vapor 7 and the working fluid liquid 8 between the heating part 5 and the cooling part 6 owing to a pressure oscillation which is self-excitedly generated.

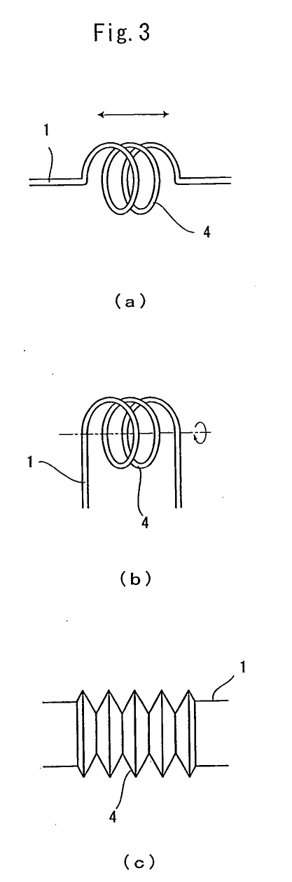

FIG. 3 shows examples relating to shapes having flexibility. The conduit of the self-excited oscillation heat pipe is formed in a coiled shape at the conduit part 4 having flexibility. According to the example shown in FIG. 3(a), the conduit 1 is deployable in an axial direction of the coil mainly at the conduit part 4. According to the example shown in FIG. 3(b), the conduit 1 is rotatable about the axis of the coil mainly at the conduit part 4. According to the example shown in FIG. 3(c), the conduit part 4 having flexibility is formed of a bellows and can be folded and extended.

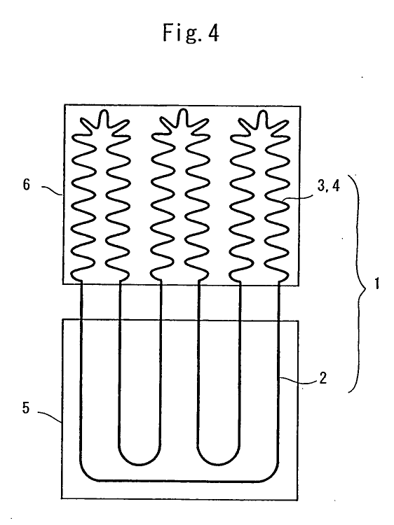

According to the example in FIG. 4, the conduit part 4 having flexibility is disposed on the cooling part 6 serving as a deformable heat transfer surface.

The conduit part 4 may be formed of a material having flexibility. As an example of the material having flexibility, there are exemplified super elastic Ti—Ni alloy or a super elastic plastic Ti alloy.

Meanwhile, shapes and materials of the container so as to allow the self-excited oscillation heat pipe to be flexible are not limited to the foregoing embodiment.

The shapes of the container so as to allow the self-excited oscillation heat pipe to be flexible are set depending on directions and dimensions of necessary flexibility, they are limited to the embodiment shown in FIG. 1 or FIG. 3. For example, the shapes of the container so as to allow the self-excited oscillation heat pipe to be flexible may be formed in a U-shape or a Q-shape. Further, a cross section of the conduit part 4 may be smaller than that of the other conduit or may be flat. Still further, the conduit part 4 may be formed of a material having flexibility and the shape of the conduit part 4 may be changed in a shape having flexibility. The container of the heat pipe is not limited to the conduit and may be formed of a container having a plate having a fluid channel therein by providing a groove inside the plate which is covered with a cover.

A material constituting the conduit part 4 may be a material having flexibility and a material other than super elastic Ti—Ni alloy or a super elastic plastic Ti alloy may be employed.

In short, the container of the self-excited oscillation heat pipe may have flexibility without losing a function of the heat pipe.

Since it is set depends on the change of a relative position and angular of a heat transfer surface or the change of the shape of the heat transfer surface as to whether on which part of the self-excited oscillation heat pipe a portion having flexibility is provided, and hence it is not limited to the embodiment shown in FIG. 1, FIG. 3, and FIG. 4. For example, in the case where the entire heat pipe is disposed on a deformable surface, the entire heat pipe may be formed to have flexibility.

In the case where the self-excited oscillation heat pipe is used in clothing, for example, in the case of a specific clothing having high thermal insulation properties such as a fireman uniform or a spacesuit, it is possible to dispose the self-excited oscillation heat pipe of the present invention on the entire clothing and the same part may be flexible.

In the case where a distance between two heat transfer surfaces is changed or in the case where two heat transfer surfaces are folded or extended, a container of the self-excited oscillation heat pipe to be disposed on the connecting part may be formed to be flexible. In the case where the self-excited oscillation heat pipe is used in a spacecraft having an deployable radiation surface, the self-excited oscillation heat pipe of the present invention may be disposed on a main unit having a heating unit such as electronic equipment and the deployable radiation surface, and a conduit part to be disposed on a connection part between the main unit and the deployable radiation surface may have flexibility.

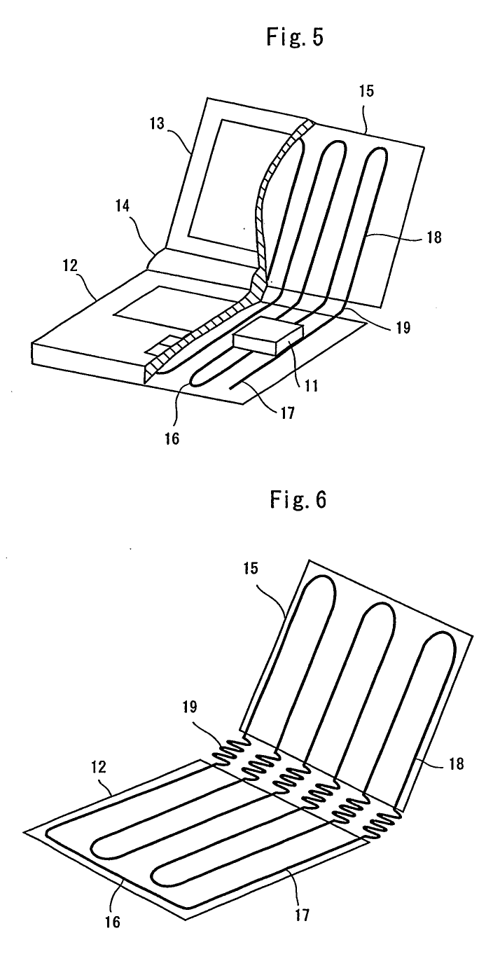

An embodiment of a computer provided with the self-excited oscillation heat pipe is described next. FIG. 5 shows a schematic perspective view and it is a partial cross sectional view so as to understand the interior thereof. In FIG. 5, a main unit 12 having a heating element 11 and the like such as a CPU and the like and a display unit 13 are connected to each other by a connection part 14, wherein a radiation surface 15 is provided on the backside of the display unit 13. The display unit 13 is attached to the main unit 12 so as to be deployable at the connection part 14.

A container of the self-excited oscillation heat pipe is formed of a conduit 16 and the conduit 16 comprises a conduit part 17 disposed on the main unit 12, a conduit part 18 disposed on the radiation surface, and a conduit part 19 for connecting between the conduit part 17 disposed on the connection part 14 and the conduit part 18. The conduit 16 is configured to reciprocate multiple times between the main unit 12 and the radiation surface 15.

The heating element 11 such as the CPU and the like is mounted in an excellent heat transfer state relative to the conduit part 17 of the self-excited oscillation heat pipe, wherein heat generated in the heating element 11 such as the CPU and the like is transferred to the radiation surface 15 from the conduit part 17 through the conduit part 19 and the conduit part 18, and it is radiated at the radiation surface 15. The conduit part 19 is formed in the foregoing flexible shape or formed of a material having flexibility, whereby even if the display unit 13 is folded or extended relative to the main unit 12, it is formed not to deteriorate a function owing to a stress generated in the container.

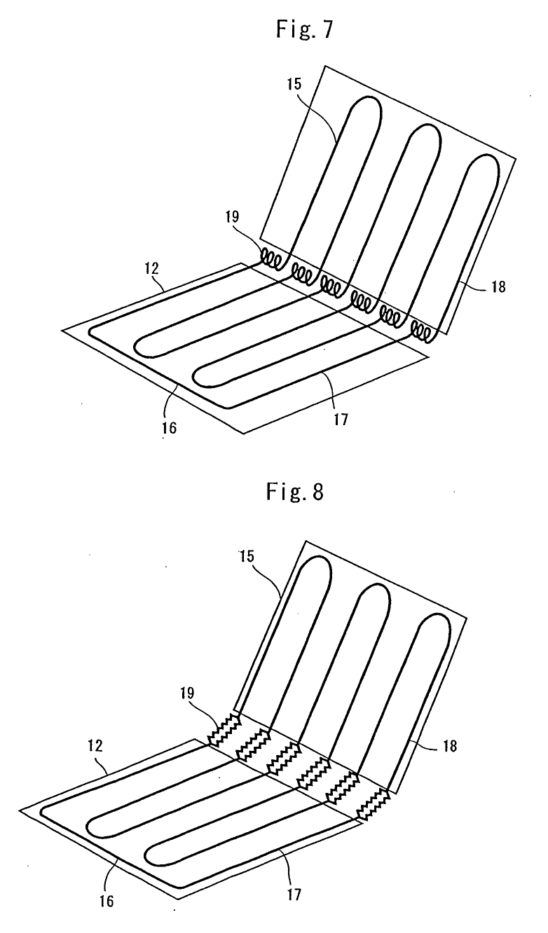

FIGS. 6 to 8 show examples where the conduit part 19 of the self-excited oscillation heat pipe has a flexible shape. In FIG. 6, at least a part of the conduit part 19 of the self-excited oscillation heat pipe is formed in a waved bent shape and has flexibility Further, in FIG. 7, at least a part of the conduit part 19 of the self-excited oscillation heat pipe is formed in a coiled shape and has flexibility Still further, in FIG. 8, at least a part of the conduit part 19 of the self-excited oscillation heat pipe has flexibility by providing a bellows thereon.

The container having flexibility is not limited to the part of the conduit part 19 but the entire container may be formed of a material having flexibility In short, the container of the self-excited oscillation heat pipe may have flexibility without impeding the flow of working fluid.

The shape and the manner of attachment of the radiation surface 15 is not limited to the foregoing embodiment. For example, the radiation surface 15 may be attached to the backside of the display unit 13 while providing the gap therebetween without being directly provided on the backside of the display unit 13. Still further, not only one piece of the radiation surface 15 but also plural pieces of radiation surface 15 may be attached. Yet further, a cooling fan may be provided on the radiation surface 15 to enhance the radiation performance.

1. A self-excited oscillation heat pipe charging working fluid in a fluid channel reciprocating multiple times between a heating portion and a cooling portion, wherein at least a part of a container constituting the fluid channel has flexibility and can be disposed at a portion which is deployable, foldable and deformable:

2. A self-excited oscillation heat pipe according to claim 1, wherein at least a part of a conduit constituting the container of the self-excited oscillation heat pipe has a flexible shape.

3. A self-excited oscillation heat pipe according to claim 2, wherein at least a part of a conduit constituting the container of the self-excited oscillation heat pipe has a coiled shape.

4. A self-excited oscillation heat pipe according to claim 2, wherein at least a part of the conduit constituting the container of the self-excited oscillation heat pipe has a waved bent shape.

5. A self-excited oscillation heat pipe according to claim 2, wherein at least a part of the conduit constituting the container of the self-excited oscillation heat pipe is formed of a bellows.

6. A self-excited oscillation heat pipe according to claim 1, wherein at least a part of the container of the self-excited oscillation heat pipe is constituted by a material having flexibility.

7. A self-excited oscillation heat pipe according to claim 6, wherein at least a part of the container of the self-excited oscillation heat pipe is constituted by super elastic alloys or supper elastic plastic alloys.

8. A self-excited oscillation heat pipe according to claim 2, wherein at least a part of the conduit constituting the container of the self-excited oscillation heat pipe disposed on a heat transfer surface has flexibility.

9. A self-excited oscillation heat pipe according to claim 8, wherein the heat transfer surface is formed inside clothing and the conduit is disposed inside the clothing.

10. A self-excited oscillation heat pipe according to claim 2, wherein at least a part of the container of the self-excited oscillation heat pipe other than the container disposed on the heat transfer surface has flexibility.

11. A self-excited oscillation heat pipe according to claim 10, wherein the self-excited oscillation heat pipe is disposed over a main unit of a spacecraft mounting electronic equipment thereon and a radiation surface connected to the main unit to be foldable in the main unit and deployable from the main unit.

12. A computer provided with a main unit having at least a CPU housed therein and a display unit foldably attached to the main unit, wherein a self-excited oscillation heat pipe having flexibility at least at a part of a container is disposed over the main unit and a backside of the display unit.

13. A computer according to claim 12, wherein the self-excited oscillation heat pipe has a flexible shape at least at a part of a conduit constituting the container.

14. A computer according to claim 13, wherein the self-excited oscillation heat pipe has a coiled shape at least at a part of the conduit constituting the container.

15. A computer according to claim 13, wherein the self-excited oscillation heat pipe has a waved bent shape at least at a part of the conduit constituting the container.

16. A computer according to claim 13, wherein the self-excited oscillation heat pipe is formed of a bellows at least at a part of the conduit constituting the container.

17. A computer according to any of claim 12, wherein at least a part of the container of the self-excited oscillation heat pipe is constituted by a material having flexibility.

18. A computer according to any of claim 17, wherein at least a part of the container of the self-excited oscillation heat pipe is constituted by super elastic alloys or supper elastic plastic alloys.

19. A computer according to claim 12, wherein a part of the container of the self-excited oscillation heat pipe is connected to a CPU or a radiation member of the CPU in an excellent heat transfer state.

20. A computer according to claim 12, wherein a fan is provided on the radiation surface provided on the backside of the display unit.
